(19) United States
(12) Patent Application Publication
(10) Pub. No.: US 2006/0175087 A1
(43) Pub. Date: Aug. 10, 2006

(54) Electronic device comprising a housing

(76) Inventors: Guenter Schelling, Moessingen (DE); Gerhard Holzwarth, Pfullingen (DE); Martin Knapp, Kirchentellinsfurt (DE); Christoph Wenger, Korntal-Muenchingen (DE)

Correspondence Address: KENYON & KENYON LLP, ONE BROADWAY, NEW YORK, NY, 10004, US

(21) Appl. No.: 10/514,642

(22) PCT Filed: May 2, 2003
(86) PCT No.: PCT/DE03/01411

§ 371 Date: Jul. 21, 2005

(30) Foreign Application Priority Data
May 25, 2002 (DE) 102 23 370.5

(51) Int. Cl. H05K 5/00

(52) U.S. Cl. 174/520

(57) ABSTRACT

An electronic device having a housing is provided, the housing having an interior space surrounded by housing walls. A torroidal coil is arranged in the interior space. Furthermore, the housing has a lead-through region which extends from the top to the bottom of the housing. In the lead-through region, which is completely surrounded by the interior space, the torroidal coil, and the housing wall a current-conducting element is accommodated.

### RELATED ART

The present invention is based on an electronic device having a housing according to the definition of the species in the independent patent claim.

Electronic devices having a housing are already known and normally include a housing wall and an interior space surrounded by the housing wall. A torroidal coil, which is used to measure a current flow, may be arranged in the interior of such a housing. To this end, a current conductor is formed in the housing, the current conductor being surrounded by the torroidal coil.

### SUMMARY OF THE INVENTION

In contrast, the electronic device according to the present invention, having the features of the independent claim, has the advantage that it allows a current-conducting element to be encircled by a torroidal coil having a core, without the need to provide a current conductor in the interior of the housing. The manufacturing expenditure for the electronic device is therefore kept low. Furthermore, the finished electronic device may later be arranged relative to a current conductor.

Further advantages and improvements are derived from the features of the dependent claims. The torroidal coil, together with an electronic evaluation circuit, is designed as a current sensor, in particular. The evaluation of the signal from the torroidal coil is able to be implemented in an especially simple manner if an electronic switching circuit is also provided inside the housing for evaluation purposes. If the lead-through region is included to accommodate a current-conducting bolt, it will be especially easy to affix the electronic device to this bolt. The electronic device, due to its very uncomplicated and robust design, is particularly suitable for use in a motor vehicle. A preferred application consists of monitoring the current flow from a battery of the motor vehicle.

### DRAWINGS

Exemplary embodiments of the present invention are shown in the drawings and elucidated in greater detail in the following description.

The figures show:

FIG. 1 a cross-section through the electronic device according to the present invention;

FIG. 2 a section along line II-II of FIG. 1; and

FIG. 3 a cross-section through the electronic device, with a current-conducting bolt guided through the lead-through region.

### BACKGROUND OF THE INVENTION

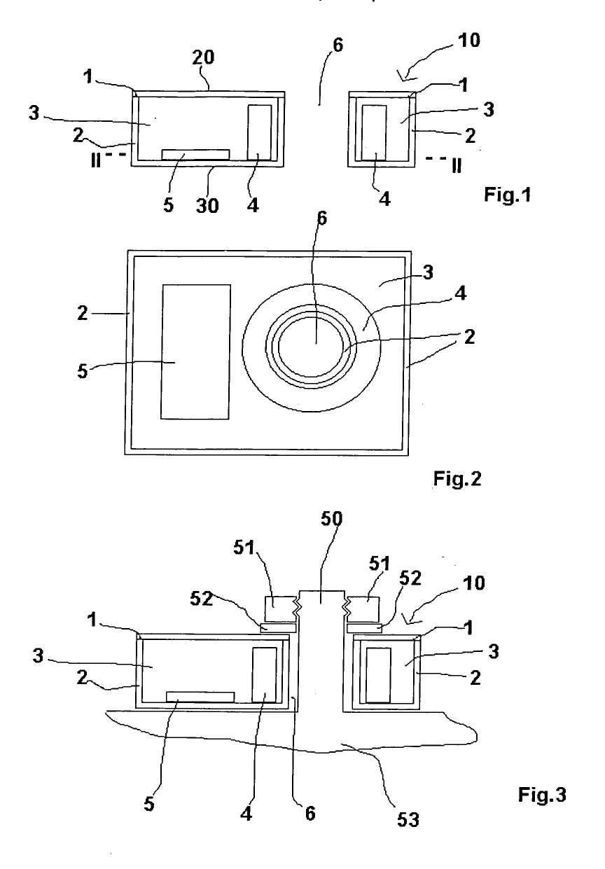

FIG. 1 shows a cross-section through an electronic device configured according to the present invention. The electronic device has a two-part housing, which is made up of a top 1 and a base 2, which each form the housing wall. Housing walls 1, 2 enclose an interior space 3 in which a torroidal coil, having core 4, and an electronic switching circuit 5 are arranged. Housing top 1 forms a topside 20 of housing 10, and housing base 2 has a bottom side 30 of housing 10. Furthermore, housing 10 has a lead-through region 6 extending from topside 20 to bottom side 30. Lead-through region 6 is a region that is kept free of the housing and which is encircled by housing 10 in the manner of a topographical annular structure. Housing 10 thus encloses lead-through region 6 with its housing walls 1, 2. This becomes especially obvious when viewing a section along plane II-II of FIG. 1, as it is illustrated in FIG. 2.

FIG. 2 shows a cross-section along plane II-II of FIG. 1. Reference numerals 2, 3, 4, 5 and 6 again denote the same items as in FIG. 1. In the sectional plane, lead-through region 6 is completely enclosed by housing wall 2, torroidal coil 4 and interior space 3. The housing is thus configured as topographical ring, which completely encloses lead-through region 6.

The electronic device formed in this manner is especially suited for measuring a current. To this end, a current conductor is inserted through lead-through region 6, in such a way that a current flow is allowed in one direction only. Torroidal coil 4 has a soft-iron core, which is arranged about lead-through region 6 in the form of a closed ring. Wound around this ring core is a measuring coil in which the actual measuring signal is generated. In a current flow through lead-through region 6 in one direction, a signal is induced in torroidal coil 4 in this manner, which is able to be detected by an electronic circuit that is arranged immediately adjacent to torroidal coil 4. For reasons of simplification, the connecting wires between torroidal coil 4 and electronic circuit 5 that are required for this purpose are not shown in FIGS. 1 and 2.

The electronic device created in this way allows an especially uncomplicated current measurement in that a current conductor is threaded through lead-through region 6. The electronic device can be finished completely and then be arranged relative to the current conductor in a subsequent step.

FIG. 3 illustrates a particularly simple arrangement of such a current conductor in lead-through region 6. FIG. 3 shows a cross-section through housing 10 analogously to FIG. 1. Reference numerals 1, 2, 3, 4, 5 and 6 once again denote the same items as in FIG. 1. In this case, a current-conducting bolt 50, which has a thread at its upper part, is shown through lead-through region 6. The thread of connecting bolt 50 cooperates with a corresponding thread of a nut 51. By threading nut 51 onto the thread of connecting bolt 50, a terminal bracket 52 is pressed down between housing top 1 and nut 51. Current bolt 50 transitions into a ground region 53 in one piece.

The device shown is suitable as grounded connection for a battery in a motor vehicle, for example. Ground region 53 is formed by the body shell of the motor vehicle to which current bolt 50 is affixed in one piece in an appropriate manner. Via lead-through region 6, the electronic device is simply placed over current bolt 50, and current-conducting bracket 52 is subsequently screwed together with nut 51. Terminal bracket 52 is connected to the negative pole of the battery by a suitable cable. With the aid of this device it is possible to monitor the entire current flow through the battery in a simple manner, and it is possibly to conclude the load state of the battery at the particular time. The load state of the battery may be calculated in electronic switching circuits 5, for instance, and be provided to other electronic devices of the motor vehicle via a bus system, which is not shown here. In this manner, an energy management of the battery of the motor vehicle is made possible.

However, other procedures for affixing the housing to a body shell and for affixing the ground cable to a ground connection in the form of a bolt are possible as well. One form of an especially secure affixation of the cable lug of the ground cable is a step at the end of the bolt, so that the cable lug has a contact surface at the bolt as well. The cable lug will then be affixed to the end of the bolt using a smaller thread. There will then be further possibilities of attaching the device:
as shown with a screw, the device together with cable lug;
the device at separate housing-attachment elements, cable lug to bolt end using a smaller thread; and
the device with large outer thread to bolt and the cable lug at bolt end using smaller thread.

However, in addition to the negative pole of the battery, any other current conductor through which a current flows is conceivable as well. If the load state of a battery in a motor vehicle is to be evaluated, a corresponding current conductor through which the entire current of the battery flows must be used. However, it may also be arranged on the positive side of the battery or in a fuse box of the motor vehicle. By the selection of an appropriate current conductor, it is also possible to monitor the current consumption of an individual component.

1-7. (canceled)

8. An electronic device, comprising:
a housing including a top, a bottom and vertical walls defining an interior space of the housing; and
a torroidal coil arranged in the interior space;
wherein the housing has a lead-through region defined by at least one vertical wall of the housing and extending from the top to the bottom of the housing, the lead-through region being concentrically surrounded by the interior space, the torroidal coil and the at least one vertical wall.

9. The electronic device as recited in claim 8, wherein the lead-through region is defined by a tubular vertical wall extending from the top to the bottom of the housing.

10. The electronic device as recited in claim 9, wherein the torroidal coil is configured as current sensor.

11. The electronic device as recited in claim 10, further comprising:
an electronic circuit configured to analyze a signal from the current sensor, wherein the electronic circuit is arranged in the interior space of the housing.

12. The electronic device as recited in claim 9, further comprising: a current-conducting bolt accommodated in the lead-through region.

13. The electronic device as recited in claim 10, wherein the electronic device is configured to be connected to a motor vehicle.

14. The electronic device as recited in claim 13, wherein the electronic device is configured to monitor the current flow of a battery of the motor vehicle.
